(19) United States
(12) Patent Application Publication
(10) Pub. No.: US 2013/0284232 A1
(43) Pub. Date: Oct. 31, 2013

(54) SOLAR CELL MODULE

(71) Applicant: Sanyo Electric Co., Ltd., Moriguchi City (JP)

(72) Inventors: Shuji Fukumochi, Kaizuka city (JP); Yosuke Ishii, Izumiotsu city (JP)

(73) Assignee: Sanyo Electric Co., Ltd., Moriguchi City (JP)

(21) Appl. No.: 13/929,068

(22) Filed: Jun. 27, 2013

Related U.S. Application Data
(63) Continuation of application No. PCT/JP2011/078751, filed on Dec. 13, 2011.

(30) Foreign Application Priority Data
Dec. 28, 2010 (JP) 2010-293027

(51) Int. Cl. H01L 31/05

(52) U.S. Cl. CPC H01L 31/0516
USPC 136/244

(57) ABSTRACT

A solar cell module includes a wiring member arranged on a back surface of a solar cell. The solar cell module comprises a wiring tab connected to a soldering region of an electrode portion of the solar cell, and an insulating sheet sandwiched between the wiring tab and the solar cell. The wiring tab includes: a flat portion being a region to be soldered; a rising portion rising from the flat portion to a height corresponding to the thickness of the insulating sheet; and an extension portion bending from the rising portion and extending in parallel with the flat portion.

### CROSS-REFERENCE TO RELATED APPLICATIONS

This is a continuation of International Application PCT/JP2011/078751, with an international filing date of Dec. 13, 2011, filed by applicant, the disclosure of which is hereby incorporated by reference in its entirety

### TECHNICAL FIELD

The invention relates to a solar cell module including wiring arranged on a back side of a solar cell.

### BACKGROUND ART

A solar cell module includes: multiple solar cell strings each including multiple solar cells electrically connected to one another; an interconnection wiring member for electrically connecting the solar cell strings to one another; and an output wiring member for outputting electric power generated by the solar cells to the outside. Heretofore, a structure where wiring members are bent and arranged on a back side of a solar cell has been under study in order to improve the power generation efficiency of a solar cell module. In such a conventional module, as illustrated in FIG. 17, insulating sheet 500 made of polyethylene terephthalate is interposed between wiring member 300 and solar cell 100 in order to prevent electrical contact between solar cell 100 and wiring member 300 attached to solar cell 100 with solder 400 (see Patent Document 1, for example).

### PRIOR ART DOCUMENT

### Patent Document

Patent Document 1: Japanese Patent Application Publication No. 2010-232701

### SUMMARY OF THE INVENTION

### Problems to be Solved by the Invention

However, as illustrated in FIG. 17, the workability in inserting the insulating sheet between the solar cell and the wiring member is sometimes poor.

In view of the above point, the invention aims to provide a solar cell module with improved workability.

An aspect of the invention provides a solar cell module comprising: a wiring member arranged on a back surface of a solar cell; and an insulating sheet sandwiched between the wiring member and the solar cell. In the solar cell module, the wiring member includes: a flat portion being a region to be soldered; a rising portion rising from the flat portion to a height level corresponding to the thickness of the insulating sheet; and an extension portion bending from the rising portion and extending in parallel with the flat portion.

### EFFECTS OF THE INVENTION

According to the invention, it is possible to easily insert the insulating sheet between the wiring member and the solar cell, and thus to provide a solar cell module with improved workability.

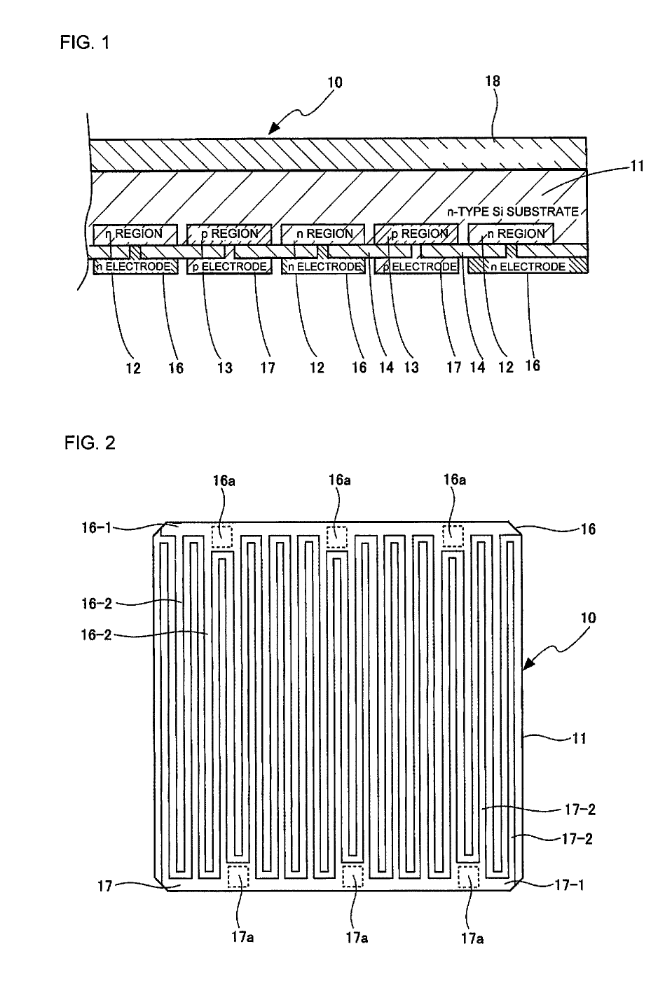

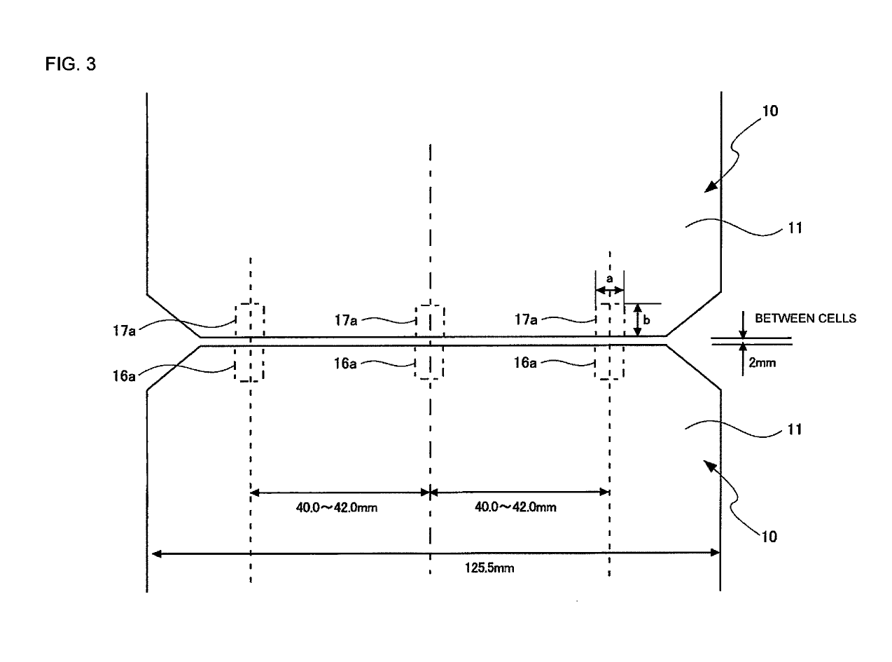

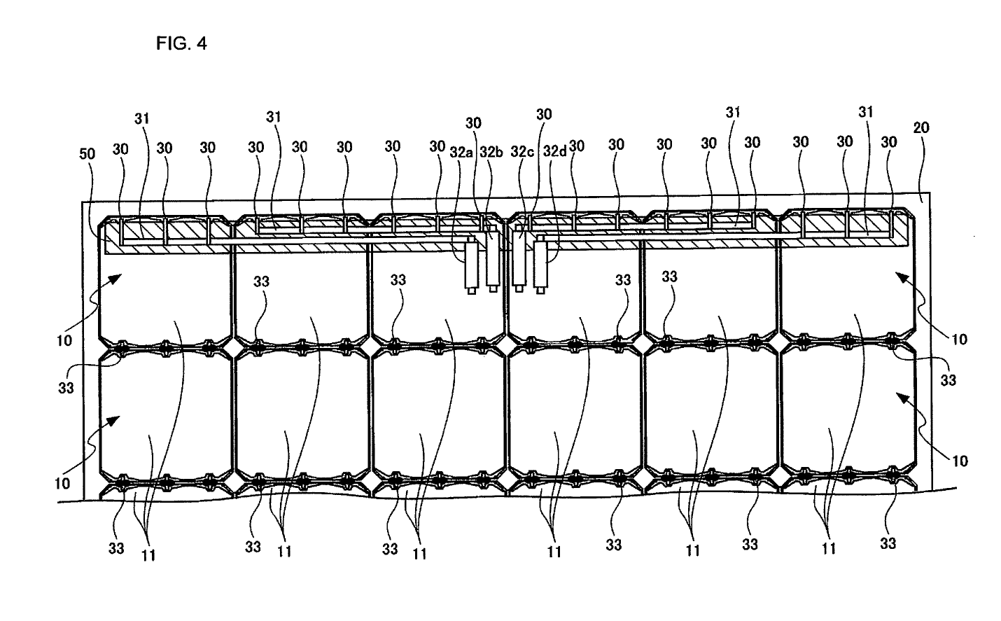

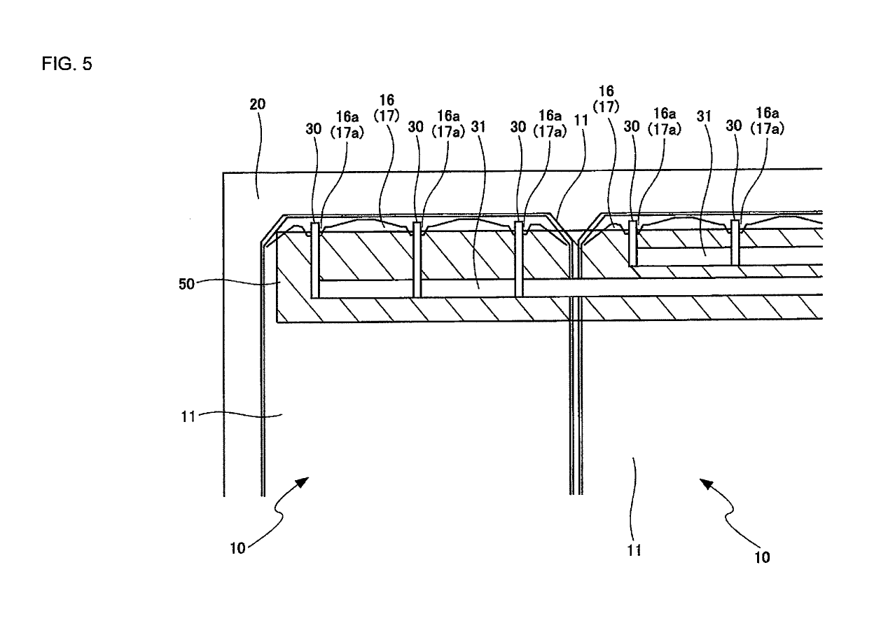

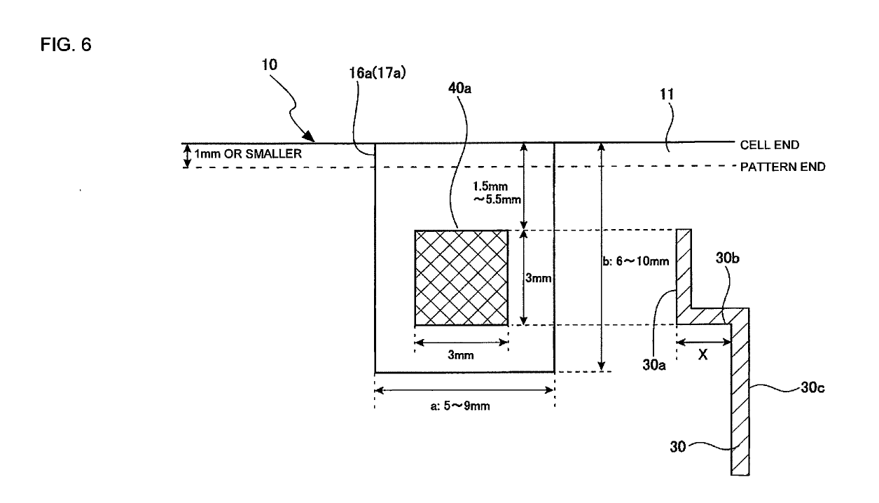

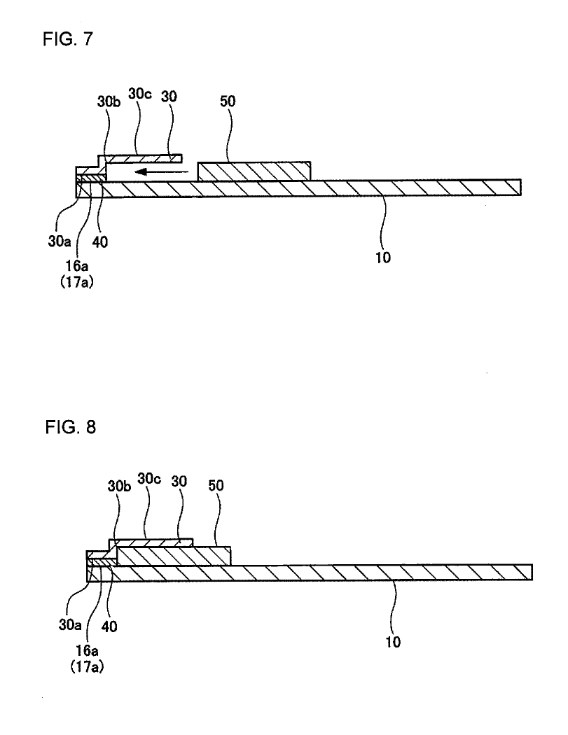

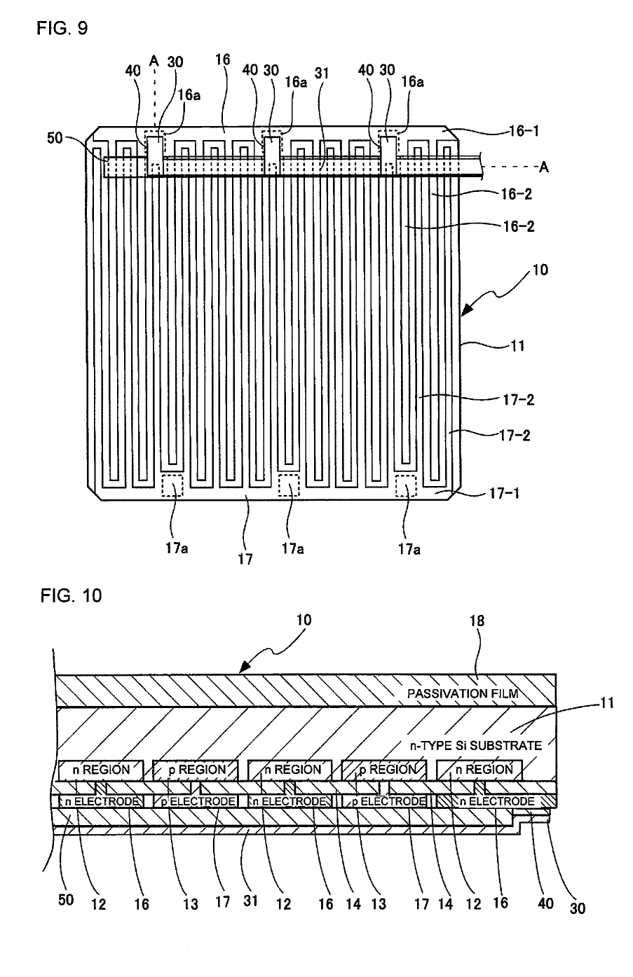

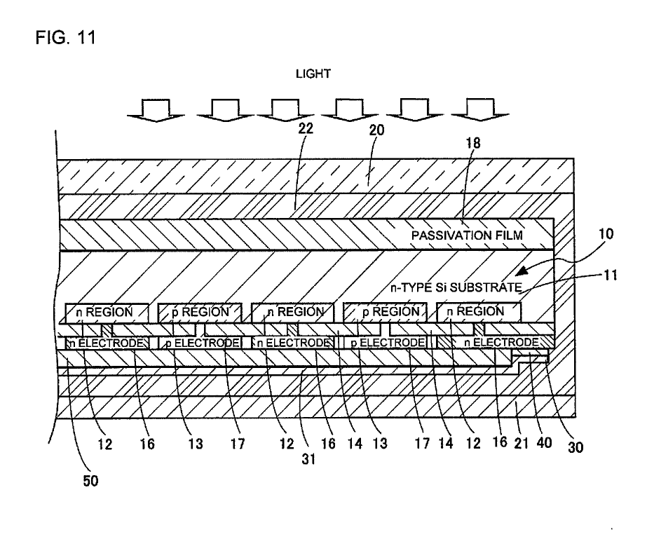

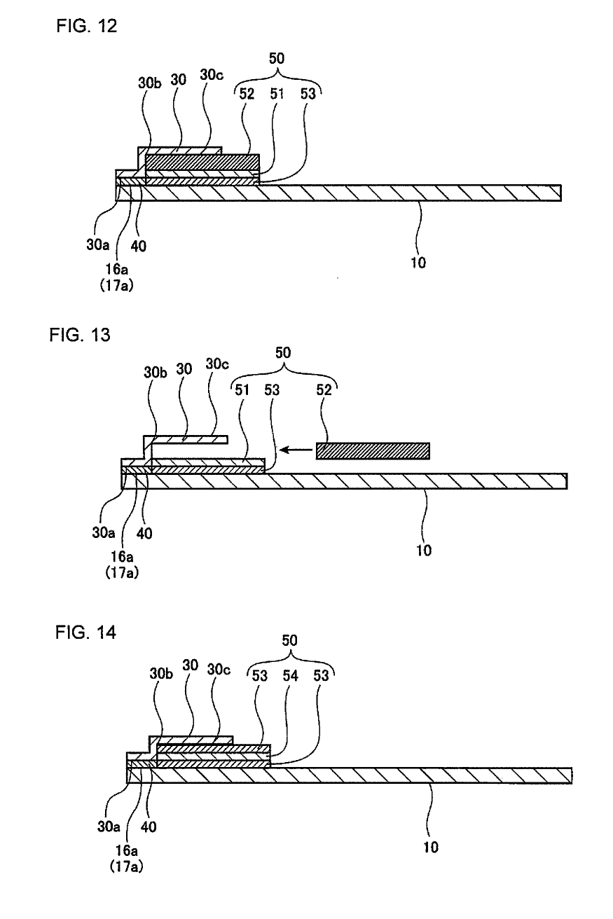

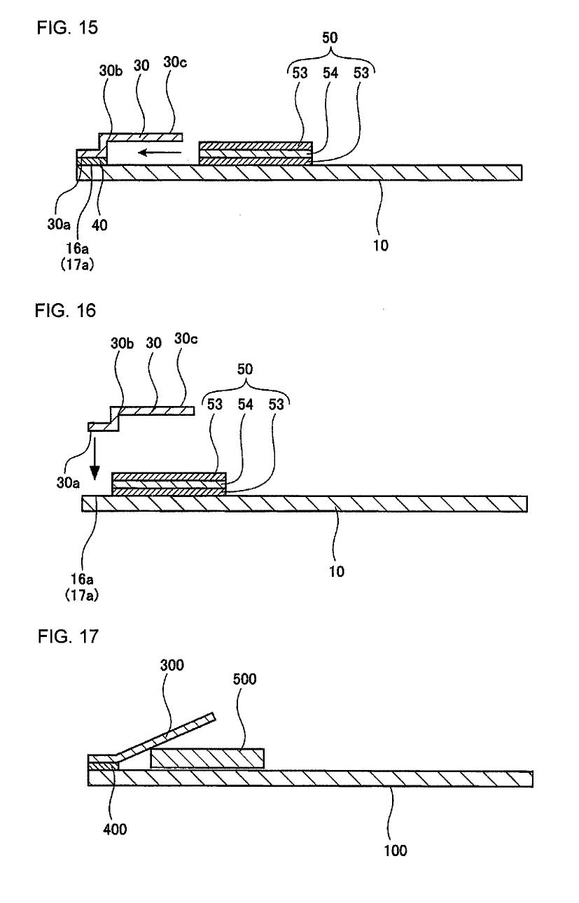

### BRIEF DESCRIPTION OF THE DRAWINGS

[FIG. 1] FIG. 1 is a schematic cross-sectional view illustrating a back contact solar cell according to an embodiment of the invention.

[FIG. 2] FIG. 2 is a schematic plan view of the back contact solar cell according to the embodiment of the invention as seen from its back surface side.

[FIG. 3] FIG. 3 is a schematic plan view illustrating an example of the back contact solar cell according to the embodiment of the invention.

[FIG. 4] FIG. 4 is a schematic plan view illustrating a connection between a wiring tab and the back contact solar cell according to the embodiment of the invention.

[FIG. 5] FIG. 5 is another schematic plan view illustrating the connection between the wiring tab and the back contact solar cell according to the embodiment of the invention.

[FIG. 6] FIG. 6 is a schematic plan view illustrating a connection portion between the wiring tab and the back contact solar cell according to the embodiment of the invention.

[FIG. 7] FIG. 7 is a schematic cross-sectional view illustrating the connection between the wiring tab and the back contact solar cell according to the embodiment of the invention.

[FIG. 8] FIG. 8 is another schematic cross-sectional view illustrating the connection between the wiring tab and the back contact solar cell according to the embodiment of the invention.

[FIG. 9] FIG. 9 is a plan view illustrating the connection between the wiring tab and the back contact solar cell according to the embodiment of the invention.

[FIG. 10] FIG. 10 is a cross-sectional view taken along the line A-A of FIG. 9.

[FIG. 11] FIG. 11 is a schematic cross-sectional view illustrating a solar cell module according to the embodiment of the invention.

[FIG. 12] FIG. 12 is a schematic cross-sectional view illustrating a connection between a wiring tab and a back contact solar cell according to a second embodiment of the invention.

[FIG. 13] FIG. 13 is another schematic cross-sectional view illustrating the connection between the wiring tab and the back contact solar cell according to the second embodiment of the invention.

[FIG. 14] FIG. 14 is a schematic cross-sectional view illustrating a connection between a wiring tab and a back contact solar cell according to a third embodiment of the invention.

[FIG. 15] FIG. 15 is another schematic cross-sectional view illustrating the connection between the wiring tab and the back contact solar cell according to the third embodiment of the invention.

[FIG. 16] FIG. 16 is another schematic cross-sectional view illustrating the connection between the wiring tab and the back contact solar cell according to the third embodiment of the invention.

[FIG. 17] FIG. 17 is a schematic cross-sectional view illustrating a connection between a wiring tab and a back contact solar cell.

### MODES FOR CARRYING OUT THE INVENTION

Embodiments of the invention are described in detail with reference to the drawings. Note that the same or equivalent parts in the drawings are given the same reference numerals and are not described again for avoiding duplicate description.

FIG. 1 is a schematic cross-sectional view illustrating a solar cell according to an embodiment of the invention. FIG. 2 is a schematic plan view of the solar cell as seen from its back surface side. The solar cell according to this embodiment is a back contact solar cell. Solar cell 10 includes p-type region 13 and n-type region 12 on a back surface side of substrate 11 formed of a semiconductor wafer made of n-type monocrystalline silicon (Si) or the like.

P-type region 13 includes multiple finger portions extending linearly in one direction. P-type region 13 also includes a bus bar portion provided along one end portion of substrate 11. The bus bar portion extends in a direction orthogonal to the one direction, and is connected to the finger portions.

N-type region 12 includes multiple finger portions extending linearly in the one direction. N-type region 12 also includes a bus bar portion provided along the other end portion of substrate 11. The bus bar portion extends in the direction orthogonal to the one direction, and is connected to the finger portions.

The finger portions of p-type region 13 and the finger portions of n-type region 12 are arranged in parallel with a predetermined clearance therebetween. Note that, although FIG. 1 illustrates the solar cell in which p-type region 13 and n-type region 12 are formed in substrate 11 by means of a thermal diffusion method, the invention is not limited to this but may employ a solar cell having a p-type semiconductor layer and an n-type semiconductor layer formed on a back surface of substrate 11 by means of a thin-film formation method.

Passivation films 18, 14 are provided on a light-receiving surface and the back surface of substrate 11 respectively in order to suppress re-coupling of carriers in these surfaces. Passivation films 18, 14 are each formed of a silicon oxide film or a silicon nitride film.

In the case where a silicon nitride film is used as passivation film 18 formed on the light-receiving surface of substrate 11, the silicon nitride film can also be used as an antireflection film (AR layer) for suppressing the reflection of sunlight on the light-receiving surface of substrate 11 owing to its refractive index of around 2.1.

Holes penetrating passivation film 14 to reach p-type region 13 and n-type region 12 are provided in predetermined portions of passivation film 14 formed on the back surface of substrate 11. The shape of each hole is not particularly limited, and a dot-shaped hole, a line-shaped hole, and the like may be used.

N-side electrode 16 is provided on n-type region 12, whereas p-side electrode 17 is provided on p-type region 13. N-side electrode 16 and p-side electrode 17 fill the holes provided in passivation film 14 and are electrically connected to n-type region 12 and p-type region 13, respectively. N-side electrode 16 includes bus bar portion 16-1 and multiple finger portions 16-2 which are provided corresponding to the bus bar portion and the multiple finger portions of n-type region 12. P-side electrode 17 includes bus bar portion 17-1 and multiple finger portions 17-2 which are provided corresponding to the bus bar portion and the multiple finger portions of p-type region 13.

A conductive material such as copper, silver, or aluminum is used as a material of electrodes 16, 17 so that the electrodes can output an electric current generated in the solar cell to the outside enough. Further, copper or the like may be grown on an aluminum base electrode by plating to form a low-resistance electrode.

As described later, soldering regions 16a, 17a to which wiring tabs are soldered are provided in bus bar portions 16-1, 17-1 to be continuous with the electrodes. In this embodiment, three soldering regions 16a and three soldering regions 17a are provided.

In this embodiment, as illustrated in FIG. 3, n-type monocrystalline silicon substrate 11 is in the form of a square of 125.5 mm by 125.5 mm. Rectangular soldering region 16a (17a) of a mm width and b mm length is provided near the center of an end portion of n-type monocrystalline silicon substrate 11. Width a is selected within a range of 5 mm to 9 mm, and length b is selected within a range of 6 mm to 10 mm. In this embodiment, rectangular soldering region 16a (17a) of 6 mm width and 7 mm length is provided, for example. In addition, soldering regions 16a (17a) of the same size as the central soldering region are provided on the right and left of the central soldering region with a clearance of 40 mm to 42 mm.

Multiple solar cells having the above configuration are arranged linearly in one direction and electrically connected to one another with wiring members to form a solar cell string. As illustrated in FIG. 3, two adjacent solar cells 10, 10 are arranged in such a way that soldering regions 16a of one of solar cells 10 and soldering regions 17a of the other solar cell are opposed to each other, respectively. As illustrated in FIG. 4, two adjacent solar cells 10, 10 are electrically connected to each other with wiring member 33. Here, wiring member 33 is connected to each of soldering regions 16a, 17a by soldering. Further, a clearance between two adjacent solar cells 10, 10 is 2 mm.

As illustrated in FIGS. 4 and 5, wiring tabs 30 connected to soldering regions 16a (17a) are connected to interconnection wiring members 31. An electric current flowing through interconnection wiring members 31 is taken out to the outside of the solar cell module through output wiring members 32a, 32b, 32c, 32d. In this way, wiring tabs 30, interconnection wiring members 31, and output wiring members 32a, 32b, 32c, 32d are provided on n-type electrode 16 and p-type electrode 17. In such a case, in order to prevent a short-circuit due to the wiring, insulating sheet 50 made of filler or an insulating material is inserted between solar cells 10 and wiring tabs 30, interconnection wiring members 31, as well as output wiring members 32a, 32b, 32c, 32d.

FIG. 6 is a plan view specifically illustrating a connection portion between a soldering region and a wiring tab. As illustrated in FIG. 6, n-type electrode 16 and p-type electrode 17 are formed in such a way that an end of n-type electrode 16 or p-type electrode 17 is located 1 mm or less, e.g., 0.74 mm away from a cell end portion of substrate 11 and that the electrodes cover the entire back surface of solar cell 10. As described previously, each soldering region 16a (17a) has a size of 6 mm×7 mm, for example. Tab connection spot 40a to which solder is to be applied has an area of 3 mm×3 mm, and is located 1.5 mm to 5.5 mm, e.g., 2.5 mm away from an end of the cell. Here, soldering region 16a (17a) is formed to be twice or more as large as tab connection spot 40a in consideration of an error in electrode formation and an alignment error in soldering.

In this embodiment, the shape of each wiring tab 30 is formed in consideration of the thickness of insulating sheet 50, made of filler or an insulating material, to be inserted between wiring tab 30 and substrate 11. Specifically, as illustrated in FIG. 6, wiring tab 30 is formed to include: flat portion 30a whose size corresponds to the size of tab connection spot 40a; rising portion 30b which rises from flat portion 30a to a height level corresponding to the thickness of insulating sheet 50; extension portion 30c which bends from rising portion 30b and extends in parallel with flat portion 30a.

As illustrated in FIG. 7, flat portion 30a of wiring tab 30 is bonded to soldering region 16a (17a) of solar cell 10 with solder 40. Wiring tab 30 attached to solar cell 10 with solder forms a space, whose thickness is equivalent to the thickness of insulating sheet 50, between extension portion 30c and solar cell 10 by use of rising portion 30b.

Wiring tab 30 has a thickness of around 100 μm to 300 μm, has a width smaller than the width of soldering region 16a (17a) but larger than the width of tab connection spot 40a, and has a length smaller than the sum of the width of insulating sheet 50 and the width of tab connection spot 40a. In this embodiment, because the width of insulating sheet 50 is 40 mm and the width of tab connection spot 40a is 3 mm, the length from a tip end of flat portion 30a to a rear end of extension portion 30c is set at 40 mm.

Flat portion 30a is formed to be longer than the length of tab connection portion 40a (3 mm) by the amount of a possible alignment error. Rising portion 30b has a height (reference sign x in FIG. 6) slightly larger than a thickness, obtained by subtracting the thickness of solder 40 from the thickness of insulating sheet 50, so that insulating sheet 50 can be inserted between the tab and the solar cell after the soldering. For example, in the case where the thickness of solder 40 is 40 μm and the thickness of insulating sheet 50 is 600 μm, height x is set slightly larger than 560 μm. Here, height x may be set equivalent to the thickness of insulating sheet 50 without subtraction of the thickness of solder 40 therefrom.

As illustrated in FIGS. 7 and 8, insulating sheet 50 of 600 μm thickness made of filler such as EVA (ethylene-vinyl acetate), PVB (polyvinyl butyral), or an olefin-based resin is inserted between extension portion 30c and solar cell 10. Since the space having a thickness equivalent to the thickness of insulating sheet 50 is formed between extension portion 30c and solar cell 10, insulating sheet 50 can be inserted to the vicinity of, or to a position in close contact with, tab connection spot 40a. Thereby, insulation in the vicinity of the contact portion between solar cell 10 and wiring tab 30 is secured by insulating sheet 50. As illustrated in FIG. 9, insulating sheet 50 is inserted between wiring tab 30 as well as interconnection wiring member 31 and solar cell 10 in such a way as to be close to or in close contact with solder 40. Since insulating sheet 50 is in close contact with the contact portion via solder 40 and arranged on n-type electrode 16 and p-type electrode 17 as illustrated in FIG. 10 which illustrates a cross section taken along the A-A line of FIG. 9, a short-circuit due to wiring tabs 30 and interconnection wiring members 31 is prevented.

In the solar cell module, p-side electrode 17 of one of two adjacent solar cells 10 and n-side electrode 16 of the other solar cell 10 are electrically connected to each other using wiring tabs 30 and interconnection wiring member 31. Further, as illustrated in FIG. 4, interconnection wiring members 31 are connected to output wiring members 32a, 32b, 32c, 32d for outputting the power to the outside of the module. Output wiring members 32a, 32b, 32c, 32d are connected to terminals of a terminal box (not illustrated). In general, output wiring members 32a, 32b, 32c, 32d are each made by covering, with solder, the entire surface of copper foil having a thickness of around 100 μm to 300 μm and a width of around 6 mm and by cutting it into a predetermined length, and are soldered to interconnection wiring members 31. Moreover, the surface of each of output wiring members 32a, 32b, 32c, 32d is covered with an insulating film.

In the solar cell module, front-surface protection member 20 made of a translucent or transparent material such as glass, translucent or transparent sealing material 22 such as EVA, multiple solar cells 10 constituting the solar cell string, back-surface-side sealing material 22, and back-surface protection member 21 are stacked from the light-receiving surface side in this order, and are subjected to lamination processing to be integrated into one unit. Through the lamination processing, as illustrated in FIG. 11, insulating sheet 50 made of filler is cross-linked, and integrated with solar cell 10 and wiring tab 30 in the state where solar cell 10 and wiring tab 30 are connected to each other. Because solar cell 10, insulating sheet 50, wiring tab 30, interconnection wiring member 31, and the like are integrated together while being in close contact with one another as illustrated in FIG. 11, no air bubbles and the like are produced.

As described above, insulating sheet 50 such as filler is integrated with solar cell 10 and wiring tab 30 while being close to or in close contact with the contact portion between solar cell 10 and wiring tab 30. Thereby, insulation from wiring tab 30 and interconnection wiring member 31 can be secured without an increase of a region for bus bar electrode 16-1 (17-1) around soldering region 16a (17a). Thus, a region for finger electrodes 16-2 (17-2) can be increased, which leads to an increase of the output. In addition, insulating sheet 50 made of a material such as filler can be installed without application of a load on solar cell 10 near the contact portion between wiring tab 30 and solar cell 10. This prevents cracking and the like of solar cell 10, which enables an increase of yield and reliability.

Further, since a gap enough to insert insulating sheet 50 is provided between solar cell 10 and wiring tab 30, insulating sheet 50 can be installed easily.

Although filler is used alone as insulating sheet 50 in the above embodiment, various materials may be used as insulating sheet 50.

As a second embodiment, with reference to FIGS. 12 and 13, a description is given of an example where an insulating sheet one side of which is provided with an adhesive layer made of a pressure sensitive adhesive, a glue, or the like is used as insulating sheet 50. Insulating sheet 50 illustrated in FIGS. 12 and 13 includes insulating base material 51 made of PET (polyethylene terephthalate), PVF (polyvinyl fluoride), PEN (polyethylene naphthalate), PE (polyethylene), or the like; and adhesive layer 53 made of a pressure sensitive adhesive, a glue, or the like and provided on one surface of insulating base material 51. EVA, EEA (ethylene-ethyl acrylate), PVB, or an olefin-based resin may be used as a resin material for the pressure sensitive adhesive. Meanwhile, a silicon-based glue, a rubber-based glue, or a urethane-based glue may be used as the glue. The thickness of insulating base material 51 is 50 μm to 75 μm, and the thickness of adhesive layer 53 is 25 μm to 45 μm. Adhesive layer 52 made of filler or the like needs to be placed on the other surface of insulating base material 51 where no adhesive layer 53 is provided. In the second embodiment, adhesive layer 53 is placed opposed to solar cell 10, and insulating base material 51 is bonded to solar cell 10 with adhesive layer 53. Moreover, adhesive layer 52 made of filler is placed on insulating base material 51 as illustrated in FIG. 13. The thickness of adhesive layer 52 is around 600 μm.

As illustrated in FIGS. 12 and 13, a space having a thickness equivalent to the thickness of insulating sheet 50 is formed between extension portion 30c of wiring tab 30 and solar cell 10, the insulating sheet being formed of adhesive layer 53, insulating base material 51, and adhesive layer 52.

Solder connection between wiring tab 30 and solar cell 10 may be carried out before insertion of insulating sheet 50, or instead may be carried out after insulating base material 51 is bonded to solar cell 10 with adhesive layer 53.

As a third embodiment, with reference to FIGS. 14 and 15, a description is given of an example where an insulating sheet both sides of which are provided with adhesive layers made of a pressure sensitive adhesive, a glue, or the like is used as insulating sheet 50. Adhesive layers 53 made of a pressure sensitive adhesive, a glue, or the like are provided on both surfaces of insulating base material 54. The thickness of insulating base material 54 is 50 μm to 75 μm, and the thickness of each adhesive layer 53 is 25 μm to 45 μm. In the third embodiment, one adhesive layer 53 is placed facing solar cell 10, and insulating sheet 50 is bonded to solar cell 10 with the other adhesive layer 53. In addition, as illustrated in FIG. 14, extension portion 30c is placed on adhesive layer 53 on insulating base material 54.

Thus, a space in size corresponding to the thickness of insulating sheet 50 including adhesive layer 53, insulating base material 54, and adhesive layer 53 is formed between extension portion 30c of wiring tab 30 and solar cell 10.

First of all, as illustrated in FIG. 15, flat portion 30a of wiring tab 30 is bonded to soldering region 16a (17a) of solar cell 10 with solder 40 in order to connect wiring tab 30 and solar cell 10 to each other with solder. Then, while insulating sheet 50 is inserted between solar cell 10 and wiring tab 30, insulating sheet 50 is bonded to solar cell 10 and wiring tab 30 with respective adhesive layers 53.

In the third embodiment, as illustrated in FIG. 16, wiring tab 30 may be connected to soldering region 16a (17a) of solar cell 10 with solder 40 after insulating sheet 50 is bonded to solar cell 10 with adhesive layer 53.

Further, using a thermoreversible resin such as EVA as adhesive layers 53 enables insulating sheet 50 to be inserted into the space between solar cell 10 and wiring tab 30 smoothly because such adhesive layers 53 are never bonded to solar cell 10 and wiring tab 30 until thermal treatment is applied thereto in lamination processing. Thereby, good workability can be achieved.

As a modification of the third embodiment, in the case where adhesive layers 53 are adhesive at normal temperature, it is also possible to bond insulating sheet 50 to a certain position of solar cell 10 with adhesive layer 53 first, and connect wiring tab 30 to soldering region 16a (17a) of solar cell 10 with solder 40 while the insulating sheet is used for positioning.

Although the solar cell module using the back contact solar cell is described as an example in the above embodiments, the invention is not limited to this but is also applicable to a solar cell module using a solar cell having electrodes on both surfaces of a semiconductor wafer.

It should be understood that the embodiments disclosed herein are exemplary in all points and do not limit the invention. The scope of the invention is defined not by the descriptions of the embodiments described above but by the scope of claims, and it is intended that the scope of the invention includes equivalents of claims and all modifications within the scope of claims.

### EXPLANATION OF REFERENCE NUMERALS

10 solar cell
11 substrate
12 n-type region
13 p-type region
16 n-type electrode
17 p-type electrode
16a, 17a soldering region
30 wiring tab
30a flat portion
30b rising portion
30c extension portion
50 insulating sheet

1. A solar cell module comprising:
a wiring member arranged on a back surface of a solar cell; and
an insulating sheet sandwiched between the wiring member and the solar cell, wherein
the wiring member includes:
a flat portion being a region to be soldered;
a rising portion rising from the flat portion to a height level corresponding to a thickness of the insulating sheet; and
an extension portion bending from the rising portion and extending in parallel with the flat portion.

2. The solar cell module according to claim 1, wherein the solar cell is provided with a soldering region having an area larger than the flat portion of the wiring member.

3. The solar cell module according to claim 1, wherein the insulating sheet is made of filler.

4. The solar cell module according to claim 1, wherein the insulating sheet includes an insulating base material and adhesive layers provided on both surfaces of the insulating base material.

5. The solar cell module according to claim 4, wherein the adhesive layers are made of a thermoreversible resin.

6. The solar cell module according to claim 1, wherein the solar cell is a back contact solar cell.
